(19) United States
(12) Patent Application Publication
(10) Pub. No.: US 2013/0009045 A1
(43) Pub. Date: Jan. 10, 2013

(54) Self-Aligned Contacts for Photosensitive Detection Devices

(75) Inventors: Edward P. Smith, Santa Barbara, CA (US); Kasey D. Smith, Santa Barbara, CA (US)

(73) Assignee: Raytheon Company, Waltham, MA (US)

(21) Appl. No.: 13/177,944

(22) Filed: Jul. 7, 2011

(51) Int. Cl. H01L 31/0232

(52) U.S. Cl. 250/214.1; 257/436; 257/E31.127

(57) ABSTRACT

A unit cell for use in an imaging system may include a layer of semiconductor material and a contact formed on the layer of semiconductor material. The layer of semiconductor material may have a bandgap such that the layer of semiconductor material absorbs photons of a particular range of wavelengths, transmits photons that are not of the particular range of wavelengths, and generates a photocurrent, referenced to a ground common, in response to the absorbed photons. The layer of semiconductor material may be formed on a substrate that transmits photons incident thereon to the layer of semiconductor material. The contact may be electrically coupled to the layer of semiconductor material such that the photocurrent is conducted from one surface of the contact to an opposing surface of the contact.

### TECHNICAL FIELD

This disclosure relates in general to photosensitive detection devices and more particularly to a photosensitive detection device system and method utilizing self-aligning contacts.

### BACKGROUND

Photodetector circuits are utilized in various devices (e.g., focal plane arrays and other photo-sensing circuits) to sense incident light in the visible and non-visible spectra. Certain photodetector circuits employ one or more position sensitive detectors (PSDs) that can measure a position of incident light upon the PSD. Conventional fabrication techniques used for small pixel photodetector devices are challenging due to the sensitivity of certain materials used and the difficulties associated with aligning fabrication layers.

### SUMMARY OF THE DISCLOSURE

A unit cell for use in an imaging system may include a layer of semiconductor material and a contact formed on the layer of semiconductor material. The layer of semiconductor material may have a bandgap such that the layer of semiconductor material absorbs photons of a particular range of wavelengths, transmits photons that are not of the particular range of wavelengths, and generates a photocurrent, referenced to a ground common, in response to the absorbed photons. The layer of semiconductor material may be formed on a substrate that transmits photons incident thereon to the layer of semiconductor material. The contact may be electrically coupled to the layer of semiconductor material such that the photocurrent is conducted from one surface of the contact to an opposing surface of the contact.

Technical advantages of certain embodiments include facilitating the fabrication of small pixel photosensitive detector devices using self-aligning processes. In certain embodiments, the contact metal of each pixel can be aligned to its mesa dimension using the same photolithography mask, thus allowing detector absorption layer thicknesses to be tailored for multiple passes in infrared radiation from the reflecting contact metal interface. In certain embodiments, a position sensitive detector that may be optimized for particular applications and uses (e.g., for use with particular desired wavelengths, including infrared wavelengths).

Other technical advantages will be readily apparent to one skilled in the art from the following figures, descriptions, and claims. Moreover, while specific advantages have been enumerated above, various embodiments may include all, some, or none of the enumerated advantages.

### BRIEF DESCRIPTION OF THE DRAWINGS

For a more complete understanding of the present disclosure and its advantages, reference is now made to the following description, taken in conjunction with the accompanying drawings, in which:

FIG. 1 is a block diagram of a portion of an imaging system, in accordance with certain embodiments;

FIG. 2 is a cross-sectional view of a substrate comprising various layers of material that may be used to form an array of photosensitive detector devices included within the imaging system of FIG. 1, in accordance with certain embodiments;

FIG. 3,is a cross-sectional view of the substrate of FIG. 2 after portions of the substrate have been selectively removed, in accordance with certain embodiments;

FIG. 4 is a cross-sectional view of the substrate of FIG. 3 after the formation and selective removal of a passivation layer outwardly from the substrate, in accordance with certain embodiments; and

FIG. 5 depicts a perspective view of an array of photosensitive detector pixels that may be included within the imaging system of FIGS. 1 through 4, in accordance with certain embodiments.

### DETAILED DESCRIPTION OF THE DISCLOSURE

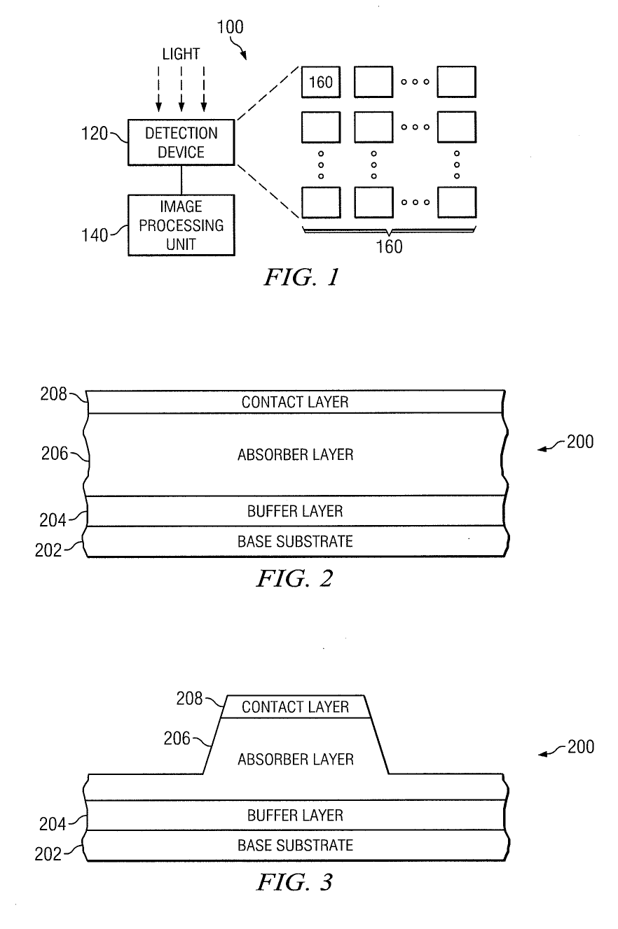

Embodiments of the present disclosure and its advantages are best understood by referring to FIGS. 1 through 5 of the drawings, like numerals being used for like and corresponding parts of the various drawings.

FIG. 1 is a block diagram illustrating an imaging system 100 according to one embodiment. Imaging system 100 may be a digital camera, video camera, or any other photographic and/or image capturing device. Imaging system 100 may include detection device 120 and image processing unit 140. Detection device 120 may be a focal plane array (FPA), active pixel sensor (APS) or any other suitable light sensing device that can capture images. Detection device 120 may include, for example, one or more diodes, charge-coupled devices (CCDs), or any other suitable photovoltaic detectors or transducers. Image processing unit 140 may be a combination of hardware, software, or firmware that is operable to receive signal information from detection device 120 and convert the signal information into an electronic image.

Detection device 120 may include an array of photosensitive unit cells 160. Photosensitive unit cells 160 may accumulate charge or produce a current and/or voltage in response to light incident upon the unit cell. In certain embodiments, each unit cell 160 may correspond to a pixel in a captured electronic image. The accumulated charge or the produced current and/or voltage may be used by processing unit 140 for processing of the incident light (e.g., to create an image representative of the incident light). In certain embodiments, one or more of photosensitive unit cells 160 may include a position sensitive detector (PSD).

As explained in greater detail below with reference to FIGS. 2-5, technical advantages of certain embodiments include using self-aligning processes to facilitate arrays of small unit cells 160 for photosensitive detector devices. In certain embodiments, for example, the contact metal of each unit cell 160 can be aligned to its underlying mesa dimension using the same photolithography mask. Particular embodiments allow multiple passes of radiation through an absorption layer due to reflections from a contact metal interface directly coupled to the absorption layer. The photon absorption of an absorption layer may be enhanced if radiation passes through the absorption layer multiple times, thereby enabling reduced thicknesses for the absorption layer. In certain instances, reducing the thickness of absorption layer may facilitate the fabrication of smaller, more efficient unit cells 160. In certain embodiments, a position sensitive detector that may be optimized for particular applications and uses (e.g., for use with particular desired wavelengths, including infrared wavelengths).

FIG. 2 is a cross-sectional view of substrate 200 comprising various layers of material that may be used to fabricate the array of photosensitive unit cells 160 of FIG. 1, in accordance with certain embodiments of the present disclosure. As shown in FIG. 2, substrate 200 may include base substrate 202, buffer layer 204, absorber layer 206, and contact layer 208. In certain embodiments, substrate 200 may include interstitial layers (not explicitly shown) within and/or between base substrate 202, buffer layer 204, absorber layer 206 and/or contact layer 208. As explained further below, substrate 200 may be used to form an array of photosensitive detector devices.

Base substrate 202 may include any substantially intrinsic semiconductor substrate (e.g., purely intrinsic or very lightly-doped), including without limitation silicon, mercury cadmium telluride, cadmium zinc tellurium, germanium, silicon carbide, gallium antimonide, gallium arsenide, gallium nitride (GaN), gallium phosphide, indium antimonide, indium arsenide, indium nitride, indium phosphide, or other suitable semiconductor material. In certain embodiments, the material or materials used for base substrate 202 may be selected based on desired characteristics for an array of light sensing devices to be fabricated from substrate 200 (e.g., a material may be selected based on having lattice properties similar to that of absorber layer 206 to be grown on base substrate 202).

Buffer layer 204 may include any suitable semiconductor substrate, including without limitation the semiconductors set forth above with respect to base substrate 202. Buffer layer 204 may be used to permit lattice matching between base substrate 202 and absorber layer 206. In certain embodiments, buffer layer 204 may be formed by epitaxially growing buffer layer 204 on base substrate 202 using vapor-phase epitaxy, liquid-phase epitaxy, solid-phase epitaxy, molecular beam epitaxy, or other suitable form of epitaxy. In the same or alternative embodiments, buffer layer 204 may be grown to a thickness of between approximately 0.0 μm and approximately 5.0 μm.

Absorber layer 206 may include one or more layers of substantially doped semiconductor material (e.g., dopant concentration between approximately 2×10¹⁴ cm⁻³ and approximately 2×10¹⁶ cm⁻³), including without limitation the semiconductor material set forth above with respect to base substrate 202. In certain embodiments, absorber layer may include one or more p-type and/or n-type semiconductor layers stacked upon each other. Absorber layer 206 may be configured to absorb photons of light incident upon absorber layer 206, such that the absorbed photons excite electrons in absorber layer 206 to generate a photocurrent by means of the photovoltaic effect. In certain embodiments, the material or materials used for absorber layer 206 may be selected based on desired characteristics for one or more photosensitive unit cells 160 to be fabricated from substrate 200 (e.g., a material may be selected with a bandgap suitable for photon absorption, and thus light detection, of a particular wavelength or range of wavelengths). In certain embodiments, absorber layer 206 may be formed by epitaxially growing absorber layer 206 on buffer layer 204 using vapor-phase epitaxy, liquid-phase epitaxy, solid-phase epitaxy, molecular beam epitaxy, or other suitable form of epitaxy (e.g., molecular beam epitaxy with flux of mercury, cadmium, and tellurium, with indium or arsenide as impurities). In the same or alternative embodiments, absorber layer 206 may be grown to a thickness of between approximately 1.0 μm and approximately 15.0 μm (e.g., to ensure absorber layer 206 is sufficiently thick to capture light of a particular intensity).

Contact layer 208 may be formed on absorber layer 206 and may include conductive material (e.g., aluminum, silver, copper, molybdenum, gold, or other suitable metal). In certain embodiments, contact layer 208 may electrically couple absorber layer 206 to other electrical and/or external electronic circuitry. Contact layer 208 may be formed on absorber layer 206 via implantation, deposition, epitaxy, or any other suitable fabrication technique. If epitaxy is used, for example, contact layer 208 may be formed by epitaxially growing contact layer 208 on absorber layer 206 using vapor-phase epitaxy, liquid-phase epitaxy, solid-phase epitaxy, molecular beam epitaxy, or other suitable form of epitaxy. If deposition is used, for example, contact layer 208 may be formed by depositing aluminum upon absorber layer 206. The material or materials used for contact layer 208, the thickness of contact layer 208, and/or other physical characteristics of contact layer 208 may be selected based on desired characteristics for one or more photosensitive unit cells 160 to be fabricated from substrate 200 (e.g., selected physical characteristics may be selected based on a desired ohmic properties for contact layer 208).

After one or more of the various layers described above have been formed, substrate 200 may be used to fabricate one or more unit cells 160 of a photosensitive detection device, as described in greater detail below.

FIG. 3 is a cross-sectional view of substrate 200 after portions of substrate 200 have been selectively removed, in accordance with certain embodiments of the present disclosure. The selective removal of portions of substrate 200 may be effected, for example, by patterning and etching substrate 200 using any suitable pattern and etch technique(s) (e.g., using photolithography followed by wet chemical etching or dry plasma etching). In certain embodiments, a photolithography mask may be used to pattern the contact layer 208, and after the contact layer 208 has been etched the same photolithography mask may be used to also pattern the absorber layer 206. In alternative embodiments, one photolithography mask may be used to pattern the contact layer 208 and then the contact layer 208 and the absorber layer 206 may be selectively removed substantially simultaneously (e.g., in the same etch).

In certain embodiments, the selective removal of portions of contact layer 208 may at least partially define a unit cell 160 in an array of photosensitive unit cells 160 and/or may define one or more areas of substrate 200 to be electrically coupled to other electrical and/or electronic Circuitry external to substrate 200. Portions of absorber layer 206 may be selectively removed, for example, to delineate and/or at least partially electrically isolate adjacent unit cells 160 from each other.

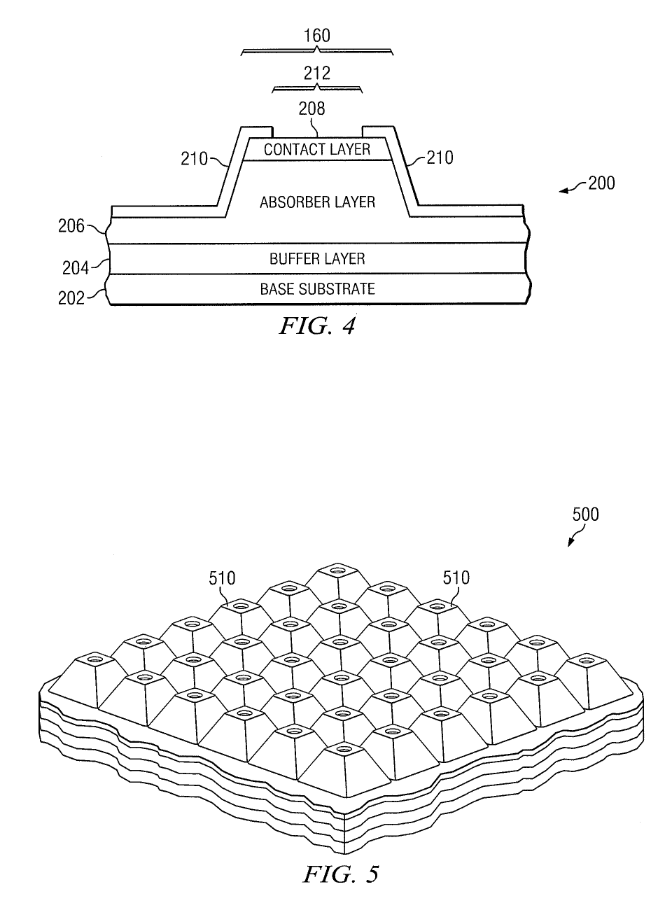

FIG. 4 is a cross-sectional view of substrate 200 after the formation and selective removal of a passivation layer 210 outwardly from substrate 200, in accordance with certain embodiments of the present disclosure. That is, after portions of absorber layer 206 and contact layer 208 have been selectively removed from substrate 200, passivation layer 210 may be formed on the remaining portions of absorber layer 206 and contact layer 208. Passivation 210 may serve to prevent or mitigate contact layer 208 and/or other materials from reacting with portions of substrate 200. Passivation layer 210 may include, for example, cadmium telluride, silicon dioxide, or any other suitable material. In certain embodiments, passivation layer 210 may be deposited on substrate 200 via thermal evaporation or molecular beam epitaxy; however, passivation layer 210 may be formed using any suitable technique(s).

After passivation layer 210 is formed, portions of passivation layer 210 may be selectively removed (e.g., via wet chemical etching or dry plasma etching) in order to expose a portion 212 of contact layer 208 disposed outwardly from each unit cell 160. Each exposed portion of contact layer 208 may in effect serve as electrical terminals for its unit cell 160. In certain embodiments, contact layer 208 may provide an etch stop for the selective removal of passivation layer 210, which may provide certain advantages over using absorption layer 206 as an etch stop.

In operation, photons of a light beam may be transmitted through base substrate 202 and buffer layer 204 to absorber layer 206. Those photons of that light beam having a particular range of wavelengths may be absorbed by absorber layer 206. For example, absorber layer 206 may be configured to absorb photons of infrared beams of light. Certain photons that initially pass through absorber layer 206 may reflect off of contact layer 208 to be subsequently absorbed as they pass back through absorber layer 206. Causing certain photons to pass through absorber layer 206 multiple times may enhance the absorption efficiency of absorber layer 206, thereby enabling thickness optimization of absorption layer 206 (e.g., the thickness of absorption layer 206 may be reduced as compared to other configurations where photons pass only once through absorption layer 206). A photocurrent may be generated in absorber layer 206 in response to the photons absorbed in the absorber layer 206. The unit-cell 160 photocurrent current may be measured by external circuitry through an electrical connection to the absorber layer 206 and contact layer 208 and an electrical connection to a ground common applied to either one or each of the absorber layer 206, buffer layer 204 or base substrate 202. By measuring the currents conducted by one or more photosensitive unit cells 160, for example, a position of light incident upon detection device 120 (or the presence of light incident upon detection device 120) may be determined.

FIG. 5 depicts a perspective view of an array 500 of photosensitive detector pixels 510 that may each correspond to one of the unit cells 160 of FIGS. 1 through 4, in accordance with certain embodiments of the present disclosure. Array 500 may include a focal plane array (FPA) and/or any other suitable imaging device. In certain embodiments, one or more photosensitive detectors 510 may each be a position sensor detector. As shown in FIG. 5, array 500 may include a plurality of photosensitive detectors 510 that are each generally mesa delineated and arranged in a grid.

In certain embodiments, array 500 of photosensitive detector pixels 510 may be formed from a single semiconductor substrate (e.g., substrate 200). In such embodiments, certain portions of one or more photosensitive detectors 510 may be common to each other. For example, each photosensitive detector pixel 510 in array 500 may have a common base substrate 202, a common buffer layer 204, and a common absorber layer 206. In addition, each individual photosensitive detector 510 of array 500 may have its own exposed portion of contact layer 208 defining a pixel in array 500.

Each photosensitive detector pixel 510 may be formed by selectively etching portions of absorber layer 206 and contact layer 208 of substrate 200 as discussed above with respect to FIGS. 2 through 4.

Advantages of the methods and systems described herein may include facilitating the fabrication of smaller, high-tolerance pixels for photosensitive detector devices using self-aligning processes. For example, by forming a contact layer on a photon absorber layer and defining the pixel features of the contact layer and the absorber layer substantially simultaneously, the contact layer may be self-aligned to the underlying mesa of the absorber layer. In addition, by forming a contact layer on a photon absorber layer, the window opening for an outwardly disposed passivation layer may be performed on the contact metal surface rather than the absorber layer surface. Particular embodiments may enhance the electric coupling of an absorber layer with an outwardly disposed contact layer. In certain embodiments, the thicknesses of the absorption layer and the contact layer may be optimized due to the fact that photons may pass through the absorption layer at least twice as they are reflected off a surface of the contact layer. Particular embodiments may provide a position sensitive detector optimized for particular applications and uses (e.g., for use with particular desired wavelengths, including infrared wavelengths). For example, a desired cut-off wavelength for light to be detected may be realized by forming an absorber layer of a suitable semiconductor composition with a bandgap supporting such cut-off wavelength.

Although the embodiments in the disclosure have been described in detail, numerous changes, substitutions, variations, alterations, and modifications may be ascertained by those skilled in the art. Additionally or alternatively, while the disclosure may be described predominantly in reference to infrared detectors, the embodiments disclosed herein may be utilized with many types of detectors including, but not limited to, visible, infrared, ultraviolet, x-ray, or other radiation detectors. It is intended that the present disclosure encompass all such changes, substitutions, variations, alterations and modifications as falling within the spirit and scope of the appended claims.

What is claimed is:

1. A unit cell for use in an imaging system, comprising:
a layer of semiconductor material having a bandgap such that the layer of semiconductor material absorbs photons of a particular range of wavelengths, transmits photons that are not of the particular range of wavelengths, and generates a photocurrent in response to the absorbed photons, the layer of semiconductor material formed on a substrate that transmits photons incident thereon to the layer of semiconductor material; and
a metal contact formed on the layer of semiconductor material and electrically coupled to the layer of semiconductor material such that the photocurrent is conducted from one surface of the contact to an opposing surface of the contact.

2. The unit cell of claim 1, wherein the metal contact is formed on the absorber layer using deposition.

3. The unit cell of claim 1, wherein the metal contact reflects photons transmitted through the layer of semiconductor material such that the photons reflected by the metal contact travel back through at least a portion of the layer of semiconductor material.

4. The unit cell of claim 1, wherein the particular range of wavelengths comprises infrared wavelengths.

5. The unit cell of claim 1, wherein the semiconductor layer comprises a doped semiconductor.

6. The unit cell of claim 1, wherein the metal contact comprises at least one of aluminum, silver, copper, molybdenum, and gold.

7. The unit cell of claim 1, wherein the layer of semiconductor material comprises mercury cadmium telluride.

8. The unit cell of claim 1, wherein the layer of semiconductor material is formed on a buffer layer configured to provide lattice matching between the layer of semiconductor material and the substrate.

9. The unit cell of claim 1, wherein the unit cell is a photosensitive detector.

10. A system for image sensing comprising:
at least one photosensitive detector comprising:
a layer of semiconductor material having a bandgap such that the layer of semiconductor material absorbs photons of a particular range of wavelengths, transmits photons that are not of the particular range of wavelengths, and generates a photocurrent in response to the absorbed photons, the layer of semiconductor material formed on a substrate that transmits photons incident thereon to the layer of semiconductor material, the photocurrent referenced to a ground common; and
a layer of ohmic material grown on the layer of semiconductor material and electrically coupled to the layer of semiconductor material such that the photocurrent is conducted through the layer of ohmic material to the ground common.

11. The unit cell of claim 1, wherein the layer of ohmic material reflects photons transmitted through the layer of semiconductor material such that the reflected photons travel back through at least a portion of the layer of semiconductor material.

12. The system of claim 10, wherein the layer of ohmic material comprises aluminum, silver, copper, molybdenum, or gold.

13. The system of claim 10, wherein the particular range of wavelengths comprises infrared wavelengths.

14. The system of claim 10, wherein the semiconductor layer semiconductor material comprises mercury cadmium telluride.

15. The system of claim 10, wherein the at least one photosensitive detector further comprises a layer of passivation material formed outwardly from at least respective portions of the layer of semiconductor material and the layer of layer of ohmic material.

16. The system of claim 10, wherein a photolithography mask is used to pattern the layer of semiconductor material, and the photolithography mask is used to pattern the layer of ohmic material.

17. A method of detecting light comprising:
transmitting photons through a transmissive substrate to a layer of semiconductor material of a photosensitive detector;
absorbing photons of a particular range of wavelengths in the layer of semiconductor material;
generating a photocurrent in the layer of semiconductor material in response to the absorbed photons; and
conducting the photocurrent through a layer of ohmic material formed on the semiconductor layer using epitaxy.

18. The method of claim 17, wherein absorbing photons of a particular range of wavelengths of semiconductor material comprises absorbing photons reflected by the layer of ohmic material.

19. The method of claim 16, wherein a photolithography mask is used to pattern both the layer of semiconductor material and the layer of ohmic material.

20. The method of claim 16, wherein portions of the layer of semiconductor material and the layer of ohmic material are selectively removed in a single etch process.
